(19) United States
(12) Patent Application Publication
(10) Pub. No.: US 2026/0182458 A1
(43) Pub. Date: Jun. 25, 2026

(54) MEMORY DEVICES AND MEMORY SYSTEMS MONITORING OPERATING VOLTAGES AND METHODS OF MONITORING OPERATING VOLTAGES

(71) Applicant: SK hynix Inc., Icheon-si Gyeonggi-do (KR)

(72) Inventors: Hyeon Jin YANG, Icheon-si Gyeonggi-do (KR); Tae Ho KIM, Icheon-si Gyeonggi-do (KR); Dong Ju YANG, Icheon-si Gyeonggi-do (KR); Se Jun HAN, Icheon-si Gyeonggi-do (KR)

(73) Assignee: SK hynix Inc., Icheon-si Gyeonggi-do (KR)

(21) Appl. No.: 19/085,319

(22) Filed: Mar. 20, 2025

(30) Foreign Application Priority Data
Dec. 19, 2024 (KR) 10-2024-0191943

(51) Int. Cl. H01L 25/065; H01L 25/18; H10B 80/00

(52) U.S. Cl. CPC H10W 90/00; H10B 80/00; H10W 90/291; H10W 90/297; H10W 90/722

(57) ABSTRACT

A memory system includes an interposer stacked over a substrate, and a memory device and a processor stacked over the interposer and connected to each other through wiring within the interposer. The memory device includes a base die and a plurality of core dies disposed over the interposer. The base die is configured to operate at an input and output power voltage. Each of the plurality of core dies is configured to generate a peripheral voltage, and each of the plurality of core dies is configured to generate a monitoring signal in response to monitoring whether the peripheral voltage supplied to one or more channel regions meets or exceeds a preset target level when an active operation is performed.

### CROSS-REFERENCE TO RELATED APPLICATIONS

The present application claims priority under 35 U.S.C § 119(a) to Korean Application No. 10-2024-0191943, filed in the Korean Intellectual Property Office on Dec. 19, 2024, the entire contents of which application is incorporated herein by reference.

### BACKGROUND

### 1. Technical Field

The present disclosure relate to memory devices and memory systems monitoring operating voltages, and methods of monitoring operating voltages.

### 2. Related Art

Stacked memory systems such as high bandwidth memory (HBM) devices are used in a wide range of applications due to their high bandwidth. Unlike conventional memory systems that use parallel data buses, stacked memory systems includes a stacked memory device including a base die and a plurality of core dies interconnected by through silicon vias (TSVs). The stacked memory device includes a physical interface, such as a physical layer (PHY) for communication with a processor. The PHY is designed for high-speed data transmission and efficient communication.

### SUMMARY

The present disclosure describes a memory system that may include an interposer stacked over a substrate, and a memory device and a processor stacked over the interposer and connected to each other through wiring within the interposer. In the present disclosure, the memory device may include a base die and a plurality of core dies disposed over the interposer. In the present disclosure, the base die may be configured to operate at an input and output power voltage. In the present disclosure, each of the plurality of core dies may be configured to generate a peripheral voltage, and each of the plurality of core dies may be configured to generate a monitoring signal in response to monitoring whether the peripheral voltage supplied to one or more channel regions meets or exceeds a preset target level when an active operation is performed.

The present disclosure describes a memory device that may include a base die including a first plurality of internal circuits configured to operate at a first operating voltage and a plurality of core dies stacked over the base die. In the present disclosure, each of the plurality of core dies may include a second plurality of internal circuits that operate at a second operating voltage and generates a monitoring signal in response to monitoring whether the second operating voltage supplied to channel regions of the plurality of core dies meets or exceeds a preset target level when an active operation is performed.

The present disclosure describes a method of monitoring an operating voltage that may include detecting a voltage level of a peripheral voltage supplied to each of a plurality of channel regions of a core die and generating a plurality of channel detection signals, generating a monitoring signal based on the plurality of channel detection signals, and outputting the monitoring signal.

The present disclosure describes a memory device that may include a base die operating at a power voltage and a plurality of core dies disposed over the base die and comprising a plurality of channel regions, each of the plurality of core dies configured to operate at a peripheral voltage and configured to generate a channel detection signal for each of the plurality of channel regions based on whether the peripheral voltage at the channel region meets or exceeds a preset target level when an active operation is performed.

### BRIEF DESCRIPTION OF THE DRAWINGS

FIG. 1 illustrates a memory system according to an embodiment of the present disclosure.

FIG. 2 illustrates a core die according to an embodiment of the present disclosure.

FIG. 3 illustrates a voltage monitoring circuit according to an embodiment of the present disclosure.

FIG. 4 illustrates a channel detection signal generation circuit according to an embodiment of the present disclosure.

FIG. 5 is a table illustrating a voltage level of a peripheral voltage according to an embodiment of the present disclosure.

FIG. 6 illustrates a monitoring signal generation circuit according to an embodiment of the present disclosure.

FIG. 7 is a table indicating selection of a channel detection signal according to an embodiment of the present disclosure.

FIG. 8 is a timing diagram during an operation in which a channel detection signal is generated according to an embodiment of the present disclosure.

FIG. 9 is a flowchart illustrating signals during operation of a voltage monitoring circuit according to an embodiment of the present disclosure.

FIG. 10 to FIG. 12 illustrate a core die in which a monitoring signal is generated and output according to an embodiment of the present disclosure.

### DETAILED DESCRIPTION

Terms such as “first” and “second” are used to distinguish between various elements and do not imply size, order, priority, quantity, or importance of the elements. For example, a first element may be referred to as a second element in one example, and the second element may be referred to as a first element in another example.

When an element is referred to as “connected” to another element, the elements may be connected directly or through one or more intervening elements between the elements. When two elements are referred to as “directly connected” one element is directly connected to the other element without an intervening element between the two elements.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

The term “binary bit set” includes a combination of logic levels of bits included in a signal. When the logic level of each bit included in a signal changes, the binary bit set of the signal is different. For example, when a signal includes two bits, the binary bit set of the signal is 00 when the logic level of each of the two bits included in the signal is logic low level, logic low level, and when the logic level of each of the two bits included in the signal is logic low level, logic high level, the binary bit set of the signal is 01.

Embodiments of the present disclosure are described in detail with reference to the accompanying drawings. Specific structural or functional descriptions of embodiments are provided as examples for illustrative purposes to describe concepts that are disclosed in the present application. Examples or embodiments in accordance with the concepts may be carried out in various forms, and the scope of the present disclosure is not limited to the examples or embodiments described in this specification.

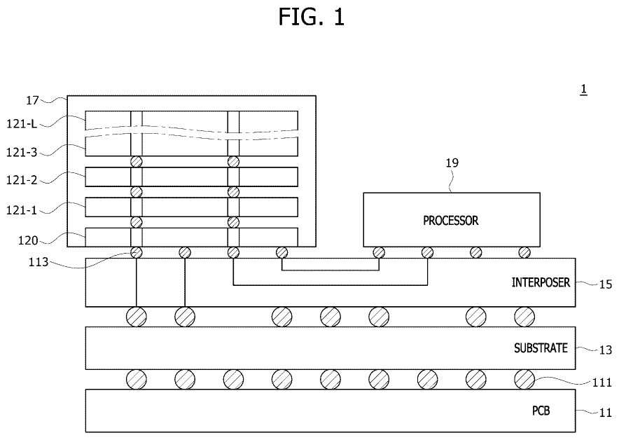

FIG. 1 illustrates a memory system 1 according to an embodiment of the present disclosure.

As shown in FIG. 1, the memory system 1 includes a printed circuit board (PCB) 11, a substrate 13, an interposer 15, a memory device 17, and a processor 19.

The printed circuit board 11 connects various electronic components to each other to form electronic circuits (not shown). The electronic circuit includes the memory system 1. A copper (Cu) layer, a solder mask, and a silk screen may be formed on the printed circuit board 11. A circuit path that transmits or transfers signals or power is formed in the copper (Cu) layer. The solder mask prevents damage to the circuit and protects a specific region where components can be soldered. The silk screen indicates location or information for electronic components as characters or symbols printed on the surface of the printed circuit board 11.

The substrate 13 is disposed over the printed circuit board 11 with bump pads in between, for example, bump pads 111, that mechanically support the interposer 15, the memory device 17, and the processor 19. The substrate 13 functions as a physical basis for the printed circuit board 11 and is an insulator. The substrate 13 may include materials such as FR4 that is an insulator made of fiberglass and epoxy resin, ceramics that can withstand high temperatures and have appropriate thermal conductivity properties, and are mainly used in high-frequency circuits, polyimide that is used as a basic material for flexible PCBs due to its flexible characteristics, and so forth.

The interposer 15 is disposed over the substrate 13 with bump pads in between and includes wiring that connects electronic components, for example, the memory device 17 and the processor 19, that have form factors or pin arrangements that do not match. The interposer 15 converts signals for communication between different interfaces, for example, DDR, HBM, and PCIe.

The memory device 17 is disposed over the interposer 15 with pads in between, for example, micro-bumps 113. The memory device 17 stores data received from the processor 19 or outputs the stored data to the processor 19 under control of the processor 19. The memory device 17 includes a base die 120 and a plurality of core dies 121-1 to 121-L, where L is an integer greater than 1. The plurality of core dies 121-1 to 121-L are stacked over the base die 120 with micro-bump pads in between. The base die 120 and the core dies 121-1 to 121-L are vertically connected to each other using through-vias. The base die 120 controls efficient data transmission between the processor 19 and the core dies 121-1 to 121-L. The base die 120 receives an input and output power voltage (voltage drain drain for IO also referred to as output stage drain power voltage) VDDQ as an operating voltage utilized during operation of internal circuits included in the base die 120. The base die 120 receives the input and output power voltage VDDQ from the printed circuit board 11 through the substrate 13 and the interposer 15. The input and output power voltage VDDQ is a voltage supplied to buffers that transmit data and is distinguished or different from a power supply voltage VDD. The core dies 121-1 to 121-L use a peripheral voltage VPERI as an operating voltage during operation of the internal circuits included in the core dies 121-1 to 121-L. The core dies 121-1 to 121-L receive the power supply voltage VDDQ through the base die 120. The core dies 121-1 to 121-L generate the peripheral voltage VPERI from the power supply voltage VDDQ. The core dies 121-1 to 121-L generate the peripheral voltage VPERI at a lower voltage level than the input and output power voltage VDDQ and use the peripheral voltage VPERI as the operating voltage. Each of the core dies 121-1 to 121-L includes a plurality of channel regions, for example, eight channel regions or sixteen channel regions, that operate independently. Each of the plurality of channel regions is allocated with a channel operating independently to receive or transmit data. The quantity L of core dies 121-1 to 121-L may be four, eight, twelve, sixteen, and so forth. For example, when each of the core dies 121-1 to 121-12 has eight channels, the core dies 121-1 to 121-4, the core dies 121-5 to 121-8, and the core dies 121-9 to 121-12 each include thirty-two channel regions, and transmit and receive data with the processor 19 in units of a rank including thirty-two channels.

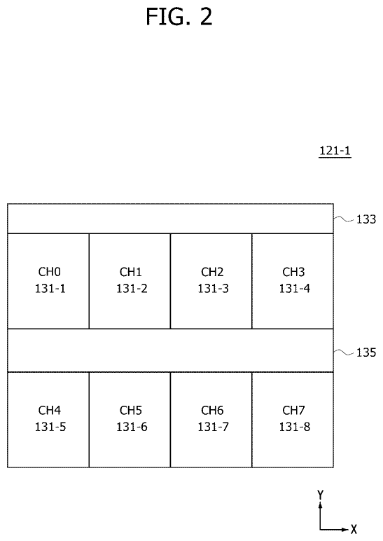

FIG. 2 illustrates a configuration of a core die 121-1 according to an embodiment of the present disclosure. The block diagrams of FIG. 2 through FIG. 7 and FIG. 10 through FIG. 12 may be implemented with logic gates or circuitry in accordance with the descriptions for FIG. 2 through FIG. 7 and FIG. 10 through FIG. 12.

As shown in FIG. 2, the core die 121-1 includes a first channel region CH0 131-1, a second channel region CH1 131-2, a third channel region CH2 131-3, a fourth channel region CH3 131-4, a fifth channel region CH5 131-5, a sixth channel region CH5 131-6, a seventh channel region CH6 131-7, an eighth channel region CH7 131-8, an edge region 133, and a center region 135.

Each of the first to eighth channel regions 131-1 to 131-8 includes a plurality of memory cell arrays that receive and store data through separate channels. The data stored in the plurality of memory cell arrays included in each of the first to eighth channel regions 131-1 to 131-8 is output through a channel allocated to each of the first to eighth channel regions 131-1 to 131-8. The channels allocated to each of the channel regions 131-1 to 131-8 function as separate data paths that may operate independently. Each of the first channel region 131-1 to the fourth channel region 131-4 is distributed in a first direction, for example, the x-direction. Each of the fifth channel regions 131-5 to the eighth channel region 131-8 is distributed in the first direction, for example, x-direction. The channel regions 131-1 to 131-4 and the channel regions 131-5 to 131-8 are distributed in a second direction, for example, the y-direction.

The edge region 133 is positioned adjacent to the channel regions 131-1 to 131-4 in the second direction, for example, the y-direction. The edge region 133 includes an internal voltage generation circuit (not shown) that generates a peripheral voltage VPERI used as an operating voltage, a plurality of TSVs, an ARE (ARray E-fuse) including electrically programmable fuses, and a control circuit (not shown) that receives the peripheral voltage VPERI and controls data input/output operations of the channel regions 131-1 to 131-8.

The center region 135 is positioned between the channel regions 131-1 to 131-4 and the channel regions 131-5 to 131-8. The center region 135 includes an internal voltage generation circuit (not shown) that generates a peripheral voltage VPERI used as an operating voltage, a plurality of through-vias, an ARE (ARray E-fuse) including electrically programmable fuses, and a control circuit (not shown) that receives the peripheral voltage VPERI and controls data input/output operations of the channel regions 131-1 to 131-8.

Each of the core dies 121-2 to 121-L includes eight channel regions, an edge region, and a center region, similar to the core die 121-1. The thirty-two channels included in four of the core dies 121-1 to 121-L are divided into ranks, and the core dies 121-1 to 121-L exchange data with the processor 19 through the thirty-two channels constituting one rank.

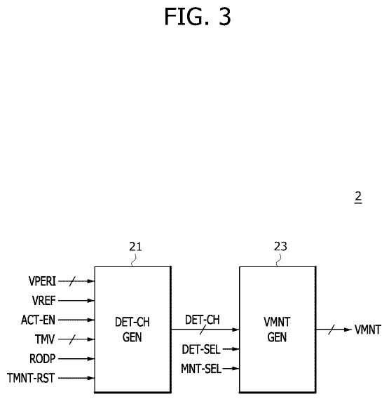

FIG. 3 illustrates a voltage monitoring circuit 2 according to an embodiment of the present disclosure.

As shown in FIG. 3, the voltage monitoring circuit 2 includes a channel detection signal generation circuit (DET-CH GEN) 21 and a monitoring signal generation circuit (VMNT GEN) 23.

The channel detection signal generation circuit 21 generates a channel detection signal DET-CH based on a peripheral voltage VPERI, a reference voltage VREF, an active signal ACT-EN, a voltage level control signal TMV, an oscillating pulse RODP, and a monitoring reset signal TMNT-RST. The channel detection signal generation circuit 21 monitors a voltage level of the peripheral voltage VPERI supplied to the channel to generate the channel detection signal DET-CH when an active operation is performed in which the memory cell array included in the channel region is accessed. The channel region indicates a channel region including the channel detection signal generation circuit 21. For example, the channel detection signal generation circuit 21 compares the peripheral voltage VPERI and the reference voltage VREF when the active signal ACT-EN is activated and generates the channel detection signal DET-CH that is activated when the peripheral voltage VPERI meets or exceeds a preset target level, for example, when the peripheral voltage VPERI falls to or below a preset target level. Throughout the present disclosure, when the peripheral voltage meets or exceeds a preset target level includes when the peripheral voltage VPERI falls to or below a preset target level. The active signal ACT-EN is activated during an active operation. The channel detection signal generation circuit 21 sets a target level at which the peripheral voltage VPERI is monitored based on the voltage level control signal TMV. For example, the channel detection signal generation circuit 21 sets the target level to a first voltage level when the voltage level control signal TMV includes a first binary bit set and sets the target level to a second voltage level when the voltage level control signal TMV includes a second binary bit set. The reference voltage VREF is set to a level corresponding to the target level, and the voltage level of the reference voltage VREF is controlled according to the voltage level control signal TMV. The channel detection signal generation circuit 21 resets the channel detection signal DET-CH based on the oscillating pulse RODP and the monitoring reset signal TMNT-RST. The oscillating pulse RODP may be generated from an oscillator (not shown) to periodically output the monitoring signal VMNT. The channel detection signal generation circuit 21 resets the channel detection signal DET-CH in synchronization with the point in time (falling edge) when the oscillating pulse RODP transitions from a logic high level to a logic low level. The channel detection signal generation circuit 21 resets the channel detection signal DET-CH in synchronization with the falling edge of the monitoring reset signal TMNT-RST regardless of the oscillating pulse RODP when the monitoring reset signal TMNT-RST is generated. The monitoring reset signal TMNT-RST is generated to control the channel detection signal DET-CH such that the monitoring reset signal TMNT-RST is not reset and maintains the logic level after the oscillating pulse RODP is generated. The quantity of channel detection signal generation circuits 21 is the same as the quantity of channel regions included in the core die. For example, in a core die including eight channel regions, a channel detection signal generation circuit 21 is included for each of the channel regions to monitor the voltage level of the peripheral voltage VPERI supplied to each channel region and generate a channel detection signal DET-CH.

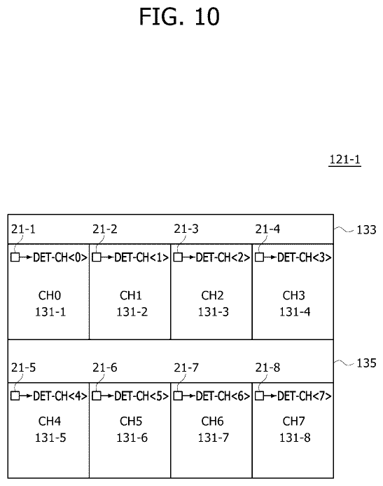

The monitoring signal generation circuit 23 is electrically connected to the channel detection signal generation circuit 21 and receives the channel detection signal DET-CH from the channel detection signal generation circuit 21. The monitoring signal generation circuit 23 generates the monitoring signal VMNT based on a channel selection signal DET-SEL and a monitoring selection signal MNT-SEL. For example, the monitoring signal generation circuit 23 generates the monitoring signal VMNT that is activated when one or more of the peripheral voltages VPERI supplied to all channel regions, for example, the channel regions 131-1 to 131-8, according to the channel detection signal DET-CH falls below a preset target level when the monitoring selection signal MNT-SEL is at a first logic level. For example, the monitoring signal generation circuit 23 generates the monitoring signal VMNT that is activated when the peripheral voltage VPERI supplied to the channel selected by the channel selection signal DET-SEL falls below the preset target level when the monitoring selection signal MNT-SEL is at a second logic level. The quantity of channel detection signals DET-CH received by the monitoring signal generation circuit 23 is the same as the quantity of channel regions included in the core die. For example, in a core die including eight channel regions, eight channel detection signals, for example, DET-CH<7:0> of FIG. 10, generated from the channel detection signal generation circuits, for example, 21-1 to 21-8 of FIG. 10, within the channel regions, are received by the monitoring signal generation circuit 23.

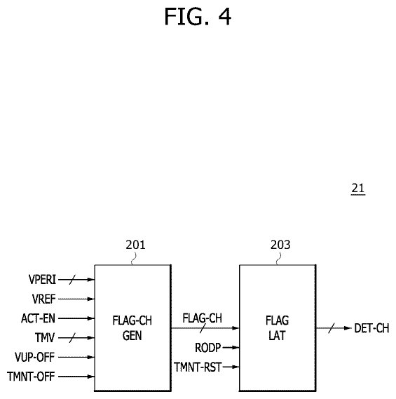

FIG. 4 illustrates a channel detection signal generation circuit 21 according to an embodiment of the present disclosure.

As shown in FIG. 4, the channel detection signal generation circuit 21 includes a channel flag generation circuit (FLAG-CH GEN) 201 and a flag latch circuit (FLAG LAT) 203.

The channel flag generation circuit 201 generates a channel flag FLAG-CH based on the peripheral voltage VPERI, a reference voltage VREF, the active signal ACT-EN, a voltage level control signal TMV, an upper limit cutoff signal VUP-OFF, and a monitoring cutoff signal TMNT-OFF. The channel flag generation circuit 201 compares the peripheral voltage VPERI and the reference voltage VREF when an active operation is performed for the channel region and the active signal ACT-EN is activated, performs a monitoring operation for the peripheral voltage VPERI, such as checking whether the peripheral voltage VPERI falls below a preset target level, and generates the channel flag FLAG-CH. For example, the channel flag FLAG-CH is generated as a pulse when the peripheral voltage VPERI falls below the preset target level. The channel flag generation circuit 201 stops monitoring the peripheral voltage VPERI based on the upper limit cutoff signal VUP-OFF. The upper limit cutoff signal VUP-OFF is activated when the peripheral voltage VPERI is equal to or higher than a preset upper limit voltage level, for example, meeting or exceeding a preset voltage level. For example, the channel flag generation circuit 201 stops monitoring the peripheral voltage VPERI according to the upper limit cutoff signal VUP-OFF that is activated when the peripheral voltage VPERI is equal to or higher than 0.8 V, which is set as the upper limit voltage level. The channel flag generation circuit 201 stops the monitoring operation for the peripheral voltage VPERI based on the monitoring cutoff signal TMNT-OFF. The monitoring cutoff signal TMNT-OFF is a test mode signal that is activated to stop the monitoring operation for the peripheral voltage VPERI. For example, in response to receiving the monitoring cutoff signal TMNT-OFF while the peripheral voltage VPERI activated, the channel flag generation circuit 201 stops the monitoring operation for the peripheral voltage VPERI.

The flag latch 203 is electrically connected to the channel flag generation circuit 201 and receives the channel flag FLAG-CH from the channel flag generation circuit 201. The flag latch 203 generates the channel detection signal DET-CH based on the channel flag FLAG-CH, the oscillating pulse RODP, and the monitoring reset signal TMNT-RST. The flag latch 203 generates the channel detection signal DET-CH based on the channel flag FLAG-CH and resets the channel detection signal DET-CH based on the oscillating pulse RODP and the monitoring reset signal TMNT-RST. The flag latch circuit 203 latches the channel flag FLAG-CH that is generated when the peripheral voltage VPERI supplied to the channel region falls below the preset target level, thereby generating the channel detection signal DET-CH as activated. The flag latch circuit 203 resets the channel detection signal DET-CH in synchronization with a falling edge of the oscillating pulse RODP. When the monitoring reset signal TMNT-RST is generated, the flag latch circuit 203 resets the channel detection signal DET-CH in synchronization with the falling edge of the monitoring reset signal TMNT-RST regardless of the oscillating pulse RODP.

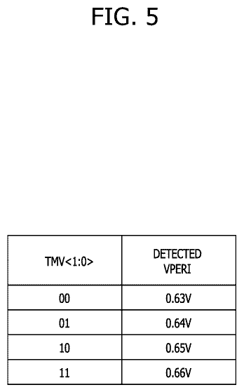

FIG. 5 is a table illustrating a voltage level of a peripheral voltage detected according to a voltage level control signal TMV in a channel detection signal generation circuit 21 according to an embodiment of the present disclosure.

As shown in a first row of FIG. 5, when a voltage level control signal TMV<1:0> includes a first binary bit set 00, a target level is set to a first voltage level 0.63 V. As shown in a second row of FIG. 5, when the voltage level control signal TMV<1:0> includes a second binary bit set 01, the target level is set to a second voltage level 0.64 V. When the voltage level control signal TMV<1:0> includes a third binary bit set, the target level is set to a third voltage level 0.65 V. When the voltage level control signal TMV<1:0> includes a fourth binary bit set, the target level is set to a fourth voltage level 0.66 V. The first voltage level 0.63 V, the second voltage level 0.64 V, the third voltage level 0.65 V, and the fourth voltage level 0.66 V are only examples and various different voltages may be set depending on the embodiment.

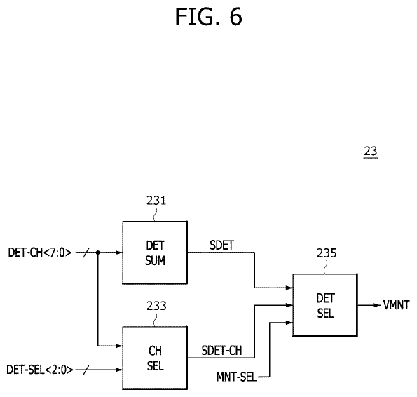

FIG. 6 illustrates a monitoring signal generation circuit 23 according to an embodiment of the present disclosure.

As shown in FIG. 6, the monitoring signal generation circuit 23 includes a detection signal summation circuit (DET SUM) 231, a channel selection circuit (CH SEL) 233, and a detection signal selection circuit (DET SEL) 235.

The detection signal summation circuit 231 generates a summation detection signal SDET based on first to eighth channel detection signals DET-CH<7:0>. The first channel detection signal DET-CH<0> is activated when a voltage level of a peripheral voltage VPERI supplied to a first channel region 131-1 falls to a preset target level or lower. The second channel detection signal DET-CH<1> is activated when the voltage level of the peripheral voltage VPERI supplied to a second channel region 131-2 falls to the preset target level or lower. The third channel detection signal DET-CH<2> is activated when the voltage level of the peripheral voltage VPERI supplied to a third channel region 131-3 falls to the preset target level or lower. The fourth channel detection signal DET-CH<3> is activated when the voltage level of the peripheral voltage VPERI supplied to a fourth channel region 131-4 falls to the preset target level or lower. The fifth channel detection signal DET-CH<4> is activated when the voltage level of the peripheral voltage VPERI supplied to a fifth channel region 131-5 falls to the preset target level or lower. The sixth channel detection signal DET-CH<5> is activated when the voltage level of the peripheral voltage VPERI supplied to a sixth channel region 131-6 falls to the preset target level or lower. The seventh channel detection signal DET-CH<6> is activated when the voltage level of the peripheral voltage VPERI supplied to a seventh channel region 131-6 falls to the preset target level or lower. The eighth channel detection signal DET-CH<7> is activated when the voltage level of the peripheral voltage VPERI supplied to an eighth channel region 131-7 falls to the preset target level or lower. The detection signal summation signal 231 adds, combines, or sums the first to eighth channel detection signals DET-CH<7:0> to generate the summation detection signal SDET. The detection signal summation circuit 231 generates the summation detection signal SDET that is activated when one or more of the first to eighth channel detection signals DET-CH<7:0> is activated. The detection signal summation circuit 231 generates the summation detection signal SDET that is activated when the voltage level of the peripheral voltage VPERI supplied to one or more of the first channel region 131-1 to the eighth channel region 131-8 falls to the preset target level or lower.

The channel selection circuit 233 generates the selection channel detection signal SDET-CH based on the first to eighth channel detection signals DET-CH<7:0> and the channel selection signal DET-SEL<2:0>. The channel selection circuit 233 selects and outputs one of the first to eighth channel detection signals DET-CH<7:0> as the selection channel detection signal SDET-CH according to the binary bit set of the channel selection signal DET-SEL<2:0>. For example, the channel selection circuit 233 selects and outputs the first channel detection signal DET-CH<0> as the selection channel detection signal SDET-CH when the channel selection signal DET-SEL<2:0> includes a first binary bit set and selects and outputs the second channel detection signal DET-CH<1> as the selection channel detection signal SDET-CH when the channel selection signal DET-SEL<2:0> includes a second binary bit set.

The detection signal selection circuit 235 is electrically connected to the detection signal summation circuit 231 and the channel selection circuit 233 to receive the summation detection signal SDET from the detection signal summation circuit 231 and receive the selection channel detection signal SDET-CH from the channel selection circuit 233. The detection signal selection circuit 235 generates a monitoring signal VMNT based on the summation detection signal SDET, the selection channel detection signal SDET-CH, and the monitoring selection signal MNT-SEL. The detection signal selection circuit 235 selects and outputs one of the summation detection signal SDET and the selection channel detection signal SDET-CH as the monitoring signal VMNT, based on the logic level of the monitoring selection signal MNT-SEL. For example, the detection signal selection circuit 235 selects and outputs the summation detection signal SDET as the monitoring signal VMNT when the monitoring selection signal MNT-SEL is at a first logic level and selects and outputs the selection channel detection signal SDET-CH as the monitoring signal VMNT when the monitoring selection signal MNT-SEL is at the second logic level.

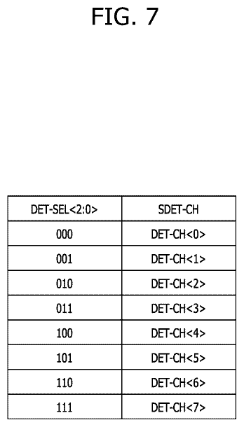

FIG. 7 is a table indicating selection of a channel detection signal selected depending on a channel selection signal DET-SEL<2:0> within a monitoring signal generation circuit 23 according to an embodiment of the present disclosure.

As shown in a first row of FIG. 7, when the channel selection signal DET-SEL<2:0> includes a first binary bit set 000, a first channel detection signal DET-CH<0> is selected and output as a selected channel detection signal SDET-CH. As shown in a second row of FIG. 7, when the channel selection signal DET-SEL<2:0> includes a second binary bit set 001, a second channel detection signal DET-CH<1> is selected and output as the selected channel detection signal SDET-CH. As shown in a third row of FIG. 7, when the channel selection signal DET-SEL<2:0> includes a third binary bit set 010, a third channel detection signal DET-CH<2> is selected and output as the selected channel detection signal SDET-CH. As shown in a fourth row of FIG. 7, when the channel selection signal DET-SEL<2:0> includes a fourth binary bit set of 011, a fourth channel detection signal DET-CH<3> is selected and output as the selected channel detection signal SDET-CH. As shown in a fifth row of FIG. 7, when the channel selection signal DET-SEL<2:0> includes a fifth binary bit set of 100, a fifth channel detection signal DET-CH<4> is selected and output as the selected channel detection signal SDET-CH. As shown in a sixth row of FIG. 7, when the channel selection signal DET-SEL<2:0> includes a sixth binary bit set of 101, a sixth channel detection signal DET-CH<5> is selected and output as the selected channel detection signal SDET-CH. As shown in a seventh row of FIG. 7, when the channel selection signal DET-SEL<2:0> includes a seventh binary bit set of 110, a seventh channel detection signal DET-CH<6> is selected and output as the selected channel detection signal SDET-CH. As shown in an eighth row of FIG. 7, when the channel selection signal DET-SEL<2:0> includes an eighth binary bit set of 111, an eighth channel detection signal DET-CH<7> is selected and output as the selected channel detection signal SDET-CH.

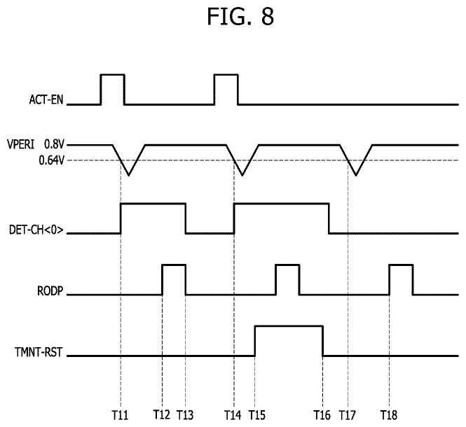

FIG. 8 is a timing diagram during an operation in which a channel detection signal DET-CH is generated in a channel detection signal generation circuit 21 according to an embodiment of the present disclosure.

At time T11, when an active operation in which a memory cell array included in a first channel region 131-1 is accessed is performed for the first time and the voltage level of the peripheral voltage VPERI supplied to the first channel region 131-1 falls to a preset target level of 0.64 V or lower, a first channel detection signal DET-CH<0> is activated at a logic high level. When an oscillating pulse RODP is generated at time T12 after the first channel detection signal DET-CH<0> is activated, the first channel detection signal DET-CH<0> is reset at a logic low level in synchronization with a falling edge of the oscillating pulse RODP at time T13.

At time T14, when the active operation, in which the memory cell array included in the first channel region 131-1 is accessed, is performed for a second time and the voltage level of the peripheral voltage VPERI supplied to the first channel region 131-1 falls to the preset target level of 0.64 V or lower, the first channel detection signal DET-CH<0> is activated at a logic high level. When the monitoring reset signal TMNT-RST is generated at time T15 after the first channel detection signal DET-CH<0> is activated, the first channel detection signal DET-CH<0> is reset at a logic low level in synchronization with a falling edge of the monitoring reset signal TMNT-RST at time T16, regardless of the oscillating pulse RODP.

At time T17, when the voltage level of the peripheral voltage VPERI supplied to the first channel region 131-1 falls to the preset target level of 0.64 V or lower while no active operation is performed on the first channel region 131-1, because the monitoring operation for the voltage level of the peripheral voltage VPERI is not performed at this time, the first channel detection signal DET-CH<0> is maintained at a logic low level. At time T18, when the oscillating pulse RODP is generated, the first channel detection signal DET-CH<0> is maintained at a logic low level.

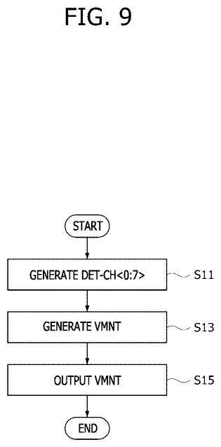

FIG. 9 is a flowchart illustrating signals during operation illustrating signals including a monitoring signal VMNT generated by a voltage monitoring circuit 2 according to an embodiment of the present disclosure. FIG. 10 to FIG. 12 illustrate a core die 121-1 that performs an operation during which a monitoring signal VMNT is generated and output by a voltage monitoring circuit 2 according to an embodiment of the present disclosure. The processes of the flowchart may be performed in a different order and may include fewer or additional processes than described and shown in FIG. 9.

As shown in FIG. 9 and FIG. 10, the channel regions 131-1 to 131-8 of the core die 121-1 include channel detection signal generation circuits 21-1 to 21-8 that generate corresponding first to eighth channel detection signals DET-CH<7:0>. For example, the channel detection signal generation circuit 21-1 that generates the first channel detection signal DET-CH<0> is within the first channel region 131-1, the channel detection signal generation circuit 21-2 that generates the second channel detection signal DET-CH<1> is within the second channel region 131-2, the channel detection signal generation circuit 21-3 that generates the third channel detection signal DET-CH<2> is within the third channel region 131-3, the channel detection signal generation circuit 21-4 that generates the fourth channel detection signal DET-CH<3> is within the fourth channel region 131-4, the channel detection signal generation circuit 21-5 that generates the fifth channel detection signal DET-CH<4> is within the fifth channel region 131-5, the channel detection signal generation circuit 21-6 that generates the sixth channel detection signal DET-CH<5> is within the sixth channel region 131-6, the channel detection signal generation circuit 21-7 that generates the seventh channel detection signal DET-CH<6> is within the seventh channel region 131-7, and the channel detection signal generation circuit 21-8 that generates the eighth channel detection signal DET-CH<7> is within the eighth channel region 131-8. The channel detection signal generation circuits 21-1 to 21-8 monitor the voltage level of the peripheral voltage VPERI supplied to the first channel region 131-1 to the eighth channel region 131-8, respectively, and generate S11 the first to eighth channel detection signals DET-CH<7:0>.

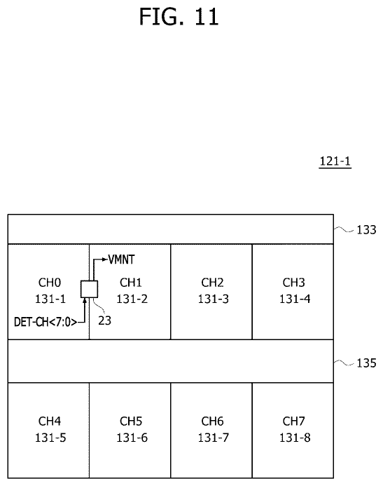

As shown in FIG. 9 and FIG. 11, a monitoring signal generation circuit 23 is located between the first channel region 131-1 and the second channel region 131-2, which monitoring signal generation circuit 23 receives the first to eighth channel detection signals DET-CH<7:0> and generates the monitoring signal VMNT. The monitoring signal generation circuit 23 generates S13 the monitoring signal VMNT that is activated when one or more of the peripheral voltages VPERI supplied to the channel regions 131-1 to 131-8 falls to a preset target level or lower. The monitoring signal generation circuit 23 generates the monitoring signal VMNT that is activated when the peripheral voltage VPERI supplied to one or more of the channel regions 131-1 to 131-8 falls to the preset target level or lower.

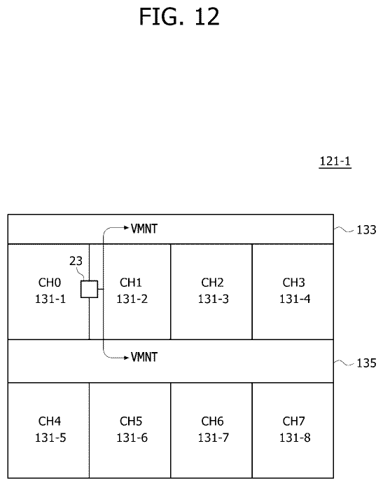

As shown in FIG. 9 and FIG. 12, the monitoring signal VMNT generated by the monitoring signal generation circuit 23 located between the first channel region 131-1 and the second channel region 131-2 of the core die 121-1 is output S15 to the edge region 133 and the center region 135. The monitoring signal VMNT output to the edge region 133 and the center region 135 is transmitted to a base die 120 through a TSV, and the base die 120 outputs the monitoring signal VMNT to the processor 19 through the interposer 15.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A memory system comprising:
an interposer stacked over a substrate; and
a memory device and a processor stacked over the interposer and connected to each other through wiring within the interposer;
wherein the memory device comprises a base die and a plurality of core dies disposed over the interposer;
wherein the base die is configured to operate at an input and output power voltage;
wherein each of the plurality of core dies is configured to generate a peripheral voltage; and
wherein each of the plurality of core dies is configured to generate a monitoring signal in response to monitoring whether the peripheral voltage supplied to one or more channel regions meets or exceeds a preset target level when an active operation is performed.

2. The memory system of claim 1, wherein each of the plurality of core dies is configured to receive the input and output power voltage and generate the peripheral voltage at a lower voltage level than the input and output power voltage.

3. The memory system of claim 1,
wherein the base die includes first internal circuits that operate at the input and output power voltage; and
wherein each of the plurality of core dies includes second internal circuits that operate at the peripheral voltage.

4. The memory system of claim 1,
wherein each of the plurality of core dies includes a plurality of channel regions, and
wherein each of the plurality of channel regions includes a channel detection signal generation circuit configured to monitor the voltage level of the peripheral voltage and generate a channel detection signal when an active operation is performed while the memory cell array is accessed.

5. The memory system of claim 4, wherein the channel detection signal generation circuit is configured to compare the peripheral voltage and a reference voltage based on an active signal and generate the channel detection signal.

6. The memory system of claim 5, wherein the channel detection signal generation circuit is configured to generate the channel detection signal that is activated when the peripheral voltage meets or exceeds the target level while the active operation is performed and the active signal is activated.

7. The memory system of claim 4, wherein the channel detection signal generation circuit is configured to control the target level based on a voltage level control signal.

8. The memory system of claim 4, wherein the channel detection signal generation circuit is configured to reset the channel detection signal in synchronization with an oscillating pulse.

9. The memory system of claim 8, wherein the channel detection signal generation circuit is configured to reset the channel detection signal in synchronization with a monitoring reset signal regardless of the oscillating pulse.

10. The memory system of claim 5, wherein the channel detection signal generation circuit comprises:
a channel flag generation circuit configured to generate a channel flag when the peripheral voltage meets or exceeds the target level based on the active signal and the reference voltage; and
a flag latch circuit configured to latch the channel flag, generate the channel detection signal, and reset the channel detection signal based on an oscillating pulse and a monitoring reset signal.

11. The memory system of claim 10, wherein the channel flag generation circuit is configured to stop monitoring the peripheral voltage when the peripheral voltage meets or exceeds a preset voltage level.

12. The memory system of claim 10, wherein the channel flag generation circuit is configured to stop monitoring the peripheral voltage when a monitoring cutoff signal is activated.

13. The memory system of claim 4, wherein each of the plurality of core dies further comprises a monitoring signal generation circuit between the plurality of channel regions and configured to monitor the peripheral voltages supplied to the plurality of channel regions based on channel detection signals generated in the plurality of channel regions to generate the monitoring signal.

14. The memory system of claim 13, wherein the monitoring signal generation circuit is configured to generate the monitoring signal by monitoring whether one or more of the peripheral voltages supplied to the plurality of channel regions meets or exceeds the target level or whether the peripheral voltage supplied to one selected from the plurality of channel regions meets or exceeds the target level.

15. The memory system of claim 13, wherein the monitoring signal generation circuit comprises:
a detection signal summation circuit configured to add the channel detection signals to generate a summation detection signal;
a channel selection circuit configured to generate a channel detection signal by selecting one of the channel detection signals based on a channel selection signal; and
a detection signal selection circuit configured to, based on a monitoring selection signal, output one of the summation detection signal and the selection channel detection signal as the monitoring signal.

16. The memory system of claim 15, wherein the detection signal summation circuit is configured to generate the summation detection signal that is activated when one of the channel detection signals is activated.

17. The memory system of claim 15, wherein the detection signal selection circuit is configured to:
output the summation detection signal as the monitoring signal when the monitoring selection signal is at a first logic level; and
output the selection channel detection signal as the monitoring signal when the monitoring selection signal is at a second logic level.

18. A memory device comprising:
a base die including a first plurality of internal circuits configured to operate at a first operating voltage; and
a plurality of core dies stacked over the base die;
wherein each of the plurality of core dies includes a second plurality of internal circuits that operate at a second operating voltage; and
wherein each of the plurality of core dies is configured to generate a monitoring signal in response to monitoring whether the second operating voltage supplied to channel regions of the plurality of core dies meets or exceeds a preset target level when an active operation is performed.

19. The memory device of claim 18,
wherein the base die is configured to receive, as the first operating voltage, an input and output power voltage supplied to a buffer that transmits data; and
wherein each of the plurality of core dies is configured to receive the input and output power voltage to generate, as the second operating voltage, a peripheral voltage at a lower voltage level than the input and output power voltage and operate at the peripheral voltage.

20. The memory device of claim 19,
wherein each of the plurality of core dies includes a plurality of channel regions; and
wherein each of the plurality of channel regions comprises a channel detection signal generation circuit configured and monitor a voltage level of the peripheral voltage to generate a channel detection signal when an active operation is performed while a memory cell array is accessed.

21. The memory device of claim 20, wherein the channel detection signal generation circuit is configured to generate the channel detection signal that is activated when the peripheral voltage meets or exceeds the target level while the active operation is performed and an active signal is activated.

22. The memory device of claim 20, wherein the channel detection signal generation circuit comprises:
a channel flag generation circuit configured to generate a channel flag when the peripheral voltage meets or exceeds the target level based on an active signal and a reference voltage; and
a flag latch circuit configured to latch the channel flag, generate the channel detection signal, and reset the channel detection signal based on an oscillating pulse and a monitoring reset signal.

23. The memory device of claim 22, wherein the channel flag generation circuit is configured to:
stop monitoring the peripheral voltage when the peripheral voltage meets or exceeds a preset voltage level; and
stop monitoring the peripheral voltage when a monitoring cutoff signal is activated.

24. The memory device of claim 22, wherein the flag latch circuit is configured to:
reset the channel detection signal in synchronization with the oscillating pulse, and
reset the channel detection signal in synchronization with a monitoring reset signal regardless of the oscillating pulse.

25. The memory device of claim 20, wherein each of the plurality of core dies further comprises a monitoring signal generation circuit between the plurality of channel regions and configured to monitor the peripheral voltages supplied to the plurality of channel regions based on the channel detection signals generated in the plurality of channel regions to generate the monitoring signal.

26. The memory device of claim 25, wherein the monitoring signal generation circuit is configured to generate the monitoring signal by monitoring whether one or more of the peripheral voltages supplied to the plurality of channel regions meets or exceeds the target level or whether the peripheral voltage supplied to one selected from the plurality of channel regions meets or exceeds the target level.

27. The memory device of claim 26, wherein the monitoring signal generation circuit comprises:
a detection signal summation circuit configured to add the channel detection signals to generate a summation detection signal;
a channel selection circuit configured to generate a selection channel detection signal by selecting one of the channel detection signals based on a channel selection signal; and
a detection signal selection circuit configured to, based on a monitoring selection signal, output one of the summation detection signal and the selection channel detection signal as the monitoring signal.

28. A method of monitoring an operating voltage, the method comprising:
detecting a voltage level of a peripheral voltage supplied to each of a plurality of channel regions of a core die and generating a plurality of channel detection signals;
generating a monitoring signal based on the plurality of channel detection signals; and
outputting the monitoring signal.

29. The method of claim 28, wherein generating the plurality of channel detection signals comprises generating one or more of the plurality of channel detection signals as activated when the peripheral voltage of one or more of the plurality of channel regions meets or exceeds target level while an active operation is performed and an active signal is activated.

30. The method of claim 29, wherein generating the channel detection signals further comprises:
controlling the target level based on a voltage level control signal; and
resetting the channel detection signal in synchronization with an oscillating pulse and a monitoring reset signal.

31. The method of claim 28, wherein generating the plurality of channel detection signals comprises monitoring whether one of the peripheral voltages supplied to the plurality of channel regions meets or exceeds the target level or whether the peripheral voltage supplied to one channel region selected from the plurality of channel regions meets or exceeds the target level.

32. A memory device comprising:
a base die operating at a power voltage; and
a plurality of core dies disposed over the base die and comprising a plurality of channel regions, each of the plurality of core dies configured to operate at a peripheral voltage and configured to generate a channel detection signal for each of the plurality of channel regions based on whether the peripheral voltage at the channel region meets or exceeds a preset target level when an active operation is performed.
